(19) United States
(12) Patent Application Publication
(10) Pub. No.: US 2025/0318347 A1
(43) Pub. Date: Oct. 9, 2025

(54) DISPLAY PANEL AND PREPARATION METHOD THEREOF

(71) Applicant: HKC CORPORATION LIMITED, SHENZHEN (CN)

(72) Inventors: Jun YIN, SHENZHEN (CN); Wanli QU, SHENZHEN (CN); Hua XIANG, SHENZHEN (CN); Yang TANG, SHENZHEN (CN); Xianfei ZHU, SHENZHEN (CN); Tian LAN, SHENZHEN (CN); Lidan YE, SHENZHEN (CN)

(73) Assignee: HKC CORPORATION LIMITED, SHENZHEN (CN)

(21) Appl. No.: 19/064,784

(22) Filed: Feb. 27, 2025

(30) Foreign Application Priority Data
Apr. 7, 2024 (CN) 202410406572.3

(51) Int. Cl. H10H 29/851; H01L 25/16; H10H 29/01

(52) U.S. Cl. CPC H10H 29/8513; H01L 25/167; H10H 29/0361

(57) ABSTRACT

A display panel and a preparation method thereof are provided. In some embodiments, a first film layer and a second film layer are combined, light conversion material is injected from a draining cavity of the second film layer to a groove of the first film layer, the second film layer is then removed, and a light conversion layer is formed within the groove.

### CROSS REFERENCE TO RELATED APPLICATIONS

This application claims priority to Chinese Patent Application No. 202410406572.3, filed Apr. 7, 2024, which is herein incorporated by reference in its entirety.

### TECHNICAL FIELD

The present disclosure relates to the field of display technologies, in particularly to a display panel and a preparation method thereof.

### BACKGROUND

In comparison with liquid crystal displays (LCD) and organic light-emitting diode (OLED) displays, micro light-emitting diodes (Micro-LED) have the advantage of high luminance, long lifespan, low power consumption, sharp contrast ratio and high color saturation. However, fabrication of a micro-LED with high luminance, high pixels per inch (PPI), and full color remains a challenge.

One technical scheme is to achieve a full-color display by combining red and green quantum dot light conversion layers with blue Micro-LEDs, which is a simpler, more efficient, and less costly approach. Two kinds of major processes are used to fabricate quantum dot light conversion layers: an inkjet printing process and a photolithographic patterning process. It is difficult to formulate the QD (quantum dots) ink for the inkjet printing process. Further, due to a limitation of precision of devices, the inkjet printing process is prone to the “coffee ring effect”, resulting in poor uniformity. Although the photolithographic patterning process enables the preparation of quantum dot light conversion layers of small sizes below 10 micrometers, the doped photolithographic agent tends to degrade the quantum dots under ultraviolet rays, thereby reducing light conversion efficiencies of the quantum dots and resulting in waste of a large amount of quantum dots.

### SUMMARY OF THE DISCLOSURE

A first technical solution adopted by the present disclosure is to provide a preparation method of a display panel. The preparation method includes: providing a light-emitting substrate, wherein the light-emitting substrate includes a supporting base and a light-emitting unit, the light-emitting unit is disposed on a side of the supporting base; preparing a first film layer on a side of the light-emitting substrate, and defining a groove on a side surface of the first film layer away from the light-emitting substrate, wherein one groove is defined corresponding to one light-emitting unit; preparing a second film layer, and defining a draining cavity within the second film layer; aligning and closely attaching the second film layer with the first film layer, and configuring the draining cavity to be in communication with the groove; injecting light conversion material into the groove through the draining cavity and curing the light conversion material; and removing the second film layer.

A second technical solution adopted by the present disclosure is to provide a display panel. The display panel is fabricated by a preparation method. The preparation method includes: providing a light-emitting substrate, wherein the light-emitting substrate includes a supporting base and a light-emitting unit, the light-emitting unit is disposed on a side of the supporting base; preparing a first film layer on a side of the light-emitting substrate, and defining a groove on a side surface of the first film layer away from the light-emitting substrate, wherein one groove is defined corresponding to one light-emitting unit; preparing a second film layer, and defining a draining cavity within the second film layer; aligning and closely attaching the second film layer with the first film layer, and configuring the draining cavity to be in communication with the groove; injecting light conversion material into the groove through the draining cavity and curing the light conversion material; and removing the second film layer.

### BRIEF DESCRIPTION OF THE DRAWINGS

To more clearly illustrate technical solutions in the present disclosure, the drawings required in the description of the embodiments will be briefly introduced below. Obviously, the drawings in the following description are only some embodiments of the present disclosure. For those of ordinary skills in the art, other drawings could be obtained based on these drawings without creative efforts.

FIG. 1 is a schematic flowchart of a preparation method of a display panel according to an embodiment of the present disclosure.

FIG. 2 is a schematic structural diagram corresponding to the operations at blocks S100 to S400 of FIG. 1.

FIG. 3 is a schematic structural diagram corresponding to the operations at blocks S500 to S700 of FIG. 1.

FIG. 4 is a schematic flowchart of an implementation of the operation at block S200 of FIG. 1.

FIG. 5 is a schematic structural diagram corresponding to the operations at blocks S210 and S220 of FIG. 4.

FIG. 6 is a schematic flowchart of an implementation of the operation at block S300 of FIG. 1.

FIG. 7 is a schematic structural diagram corresponding to an implementation of the operations at blocks S310 to S330 of FIG. 6.

FIG. 8 is a schematic sectional structural diagram along a direction A-A of FIG. 7.

FIG. 9 is a schematic structural diagram corresponding to another implementation of the operations at blocks S310 to S330 of FIG. 6.

FIG. 10 is a top view schematic structural diagram of the draining cavity and the corresponding groove according a first embodiment of the present disclosure.

FIG. 11 is a schematic sectional structural diagram along a direction B-B of FIG. 10.

FIG. 12 is a schematic sectional structural diagram along a direction E-E of FIG. 10.

FIG. 13 is a top view schematic structural diagram of the draining cavity and the corresponding groove according a second embodiment of the present disclosure.

FIG. 14 is a schematic sectional structural diagram along a direction F-F of FIG. 13.

FIG. 15 is a top view schematic structural diagram of the draining cavity and the corresponding groove according a third embodiment of the present disclosure.

FIG. 16 is a top view schematic structural diagram of the draining cavity and the corresponding groove according a fourth embodiment of the present disclosure.

FIG. 17 is a top view schematic structural diagram of the draining cavity and the corresponding groove according a fifth embodiment of the present disclosure.

FIG. 18 is a schematic flowchart of an implementation of the operation at block S500 of FIG. 1.

FIG. 19 is a schematic flowchart of a specific implementation of the operation at block S500 of FIG. 1.

FIG. 20 is a schematic structural diagram corresponding to the operation at block S521 of FIG. 19.

FIG. 21 is a top view schematic structural diagram of the draining cavity and the corresponding groove according a sixth embodiment of the present disclosure.

FIG. 22 is a schematic diagram of a roller transfer printing process of the present disclosure.

FIG. 23 is a schematic structural diagram of a display panel according to an embodiment of the present disclosure.

Reference Numerals: 10, light-emitting substrate; 11, supporting base; 12, light-emitting unit; 120, epitaxial layer; 121, buffer layer; 122, first conductivity type semiconductor structure; 123, quantum well structure; 124, second conductivity type semiconductor structure; 125, electric current spreading layer; 130, electrode layer; 131, P-type electrode; 132, N-type electrode; 13, insulating layer; 20, first film layer; 21, groove; 211, first groove; 212, second groove; 213, third groove; 30, second film layer; 310, draining cavity; 310A, first draining cavity; 310B, second draining cavity; 310C, third draining cavity; 311, inlet port; 312, outlet port; 313, fluid-guiding port; 314, first channel; 315, second channel; 316, third channel; 320, first layer structure; 320A, side face; 330, second layer structure; 40, light conversion layer; 41, first light conversion layer; 42, second light conversion layer; 43, to-be-removed conversion layer; 50, solid mold; 60, to-be-transferred substrate; 70, driving substrate; 100, display panel.

### DETAILED DESCRIPTION

Technical solutions of embodiments of the present disclosure are described in detail below in conjunction with the accompanying drawings.

In the following description, specific details such as particular system structures, interfaces, techniques or etc. are presented for the purpose of illustration and not for the purpose of limitation, to facilitate a thorough understanding of the present disclosure.

The technical solutions in embodiments of the present disclosure will be described clearly and thoroughly in conjunction with accompanying drawing of the embodiments of the present disclosure. Obviously, the described embodiments are only a part of the embodiments, but not all of them. All other embodiments by a person of ordinary skills in the art based on embodiments of the present disclosure without creative efforts should all be within the protection scope of the present disclosure.

The terms ‘first’, ‘second’, and ‘third’ in this disclosure are only for the purpose of description and cannot be construed as indicating or implying relative importance or implicitly indicating the number of technical features referred to. Therefore, the features preceded with ‘first’, ‘second’, and ‘third’ may explicitly or implicitly include at least one of the features. In the description of the present disclosure, ‘a plurality of’ means at least two, such as two, three, etc., unless otherwise specifically defined. All directional indicators (such as up, down, left, right, front, back . . . ) in embodiments of the present disclosure are only used to explain a motion state, a relative positional relationship between the components in a specific posture (as shown in the drawings). If the specific posture changes, then the directional indication will change accordingly. In addition, the terms ‘include’, ‘comprise’ and any variations thereof are intended to cover non-exclusive inclusion. For example, a process, a method, a system, a product, or a device that includes a series of operations or units is not limited to the listed operations or units, but optionally includes unlisted operations or units, or optionally also includes other operations or units inherent to these processes, methods, products or devices.

Reference to ‘embodiment(s)’ herein means that a specific feature, structure, or characteristic described in conjunction with the embodiments may be included in at least one embodiment of the present disclosure. The appearance of this phrase in various locations in the specification does not necessarily refer to the same embodiment, nor is it an independent or alternative embodiment mutually exclusive with other embodiments. Those skilled in the art may explicitly and implicitly understand that the embodiments described herein may be combined with other embodiments.

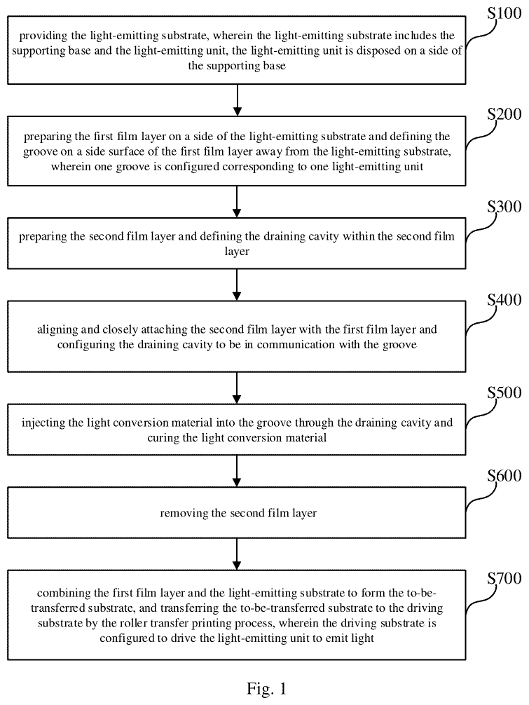

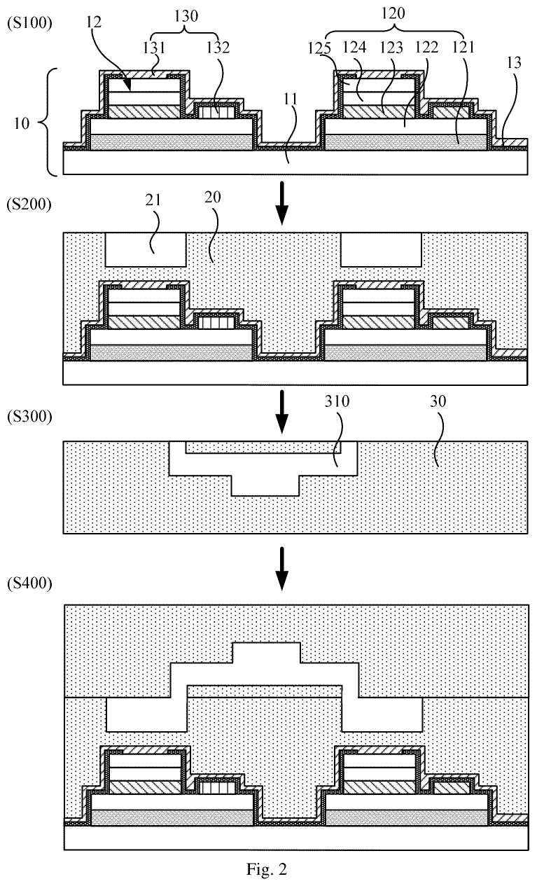

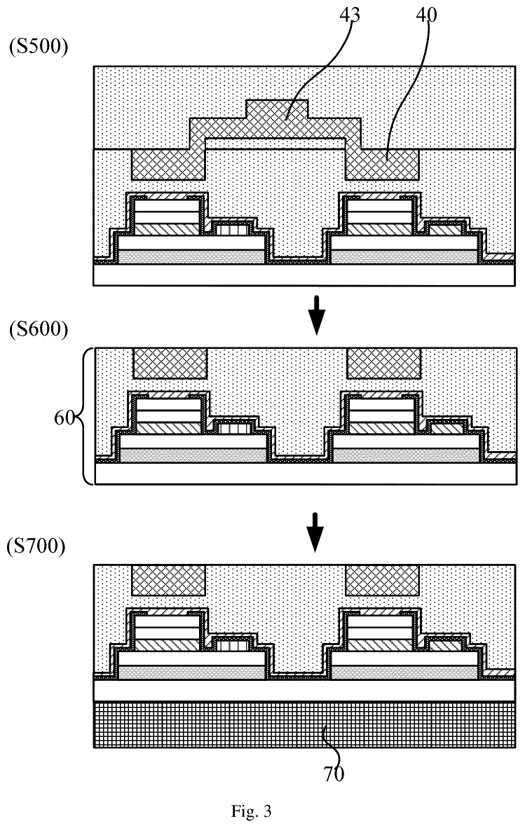

As illustrated in FIG. 1 to FIG. 3, FIG. 1 is a schematic flowchart of a preparation method of a display panel according to an embodiment of the present disclosure, FIG. 2 is a schematic structural diagram corresponding to the operations at blocks S100 to S400 of FIG. 1, and FIG. 3 is a schematic structural diagram corresponding to the operations at blocks S500 to S700 of FIG. 1.

A preparation method of a display panel is provided in the present disclosure. The preparation method of the display panel includes: providing a light-emitting substrate 10, wherein the light-emitting substrate 10 includes a supporting base 11 and a light-emitting unit 12, the light-emitting unit 12 is disposed on a side of the supporting base 11; preparing a first film layer 20 on a side of the light-emitting substrate 10, and defining a groove 21 on a side surface of the first film layer 20, wherein one groove 21 is defined corresponding to one light-emitting unit 12; preparing a second film layer 30, and defining a draining cavity 310 within the second film layer 30; aligning and closely attaching the second film layer 30 with the first film layer 20, and configuring the draining cavity 310 to be in communication with the groove 21; injecting light conversion material into the groove 21 through the draining cavity 310 and curing the light conversion material; removing the second film layer 30.

In some embodiments of the present disclosure, the first film layer 20 and the second film layer 30 are combined, the light conversion material is injected from the draining cavity 310 of the second film layer 30 into the groove 21 of the first film layer 20, the second film layer 30 is then removed, and a light conversion layer 40 is formed within the groove 21. This technical approach is used to prepare the light conversion layer 40 instead of the existing inkjet printing and photolithographic patterning processes. In comparison with the related art, this technical approach avoids the problems of poor uniformity and the low light conversion efficiencies of the light conversion layer 40. The poor uniformity is due to the “coffee ring effect” easily occurred in the inkjet printing process. The low light conversion efficiencies are due to the photolithographic process. That is, in comparison with the related art, the implementation provided in the present disclosure may enhance the uniformity and light conversion efficiencies of the light conversion layer 40.

In some embodiments, specific steps of the preparation method of the display panel are illustrated as follows.

At block S100: providing the light-emitting substrate, wherein the light-emitting substrate includes the supporting base and the light-emitting unit, the light-emitting unit is disposed on a side of the supporting base.

Specifically, the light-emitting substrate 10 is provided. The light-emitting substrate 10 includes the supporting base 11 and the light-emitting unit 12. The light-emitting unit 12 is disposed on a side of the supporting base 11. There are a plurality of light-emitting units 12. The plurality of light-emitting units 12 are arranged in an array on a side of the supporting base 11.

The light-emitting unit 12 is a micro light-emitting diode.

In the present embodiment, the light-emitting unit 12 is configured to emit the blue light. The supporting base 11 is a sapphire supporting base. The supporting base 11 may also be made from other materials. The materials of the supporting base 11 are not limited here and may be selected per actual requirements.

In some embodiments, an array of the light-emitting units 12 is obtained by an epitaxial growth process of the light-emitting unit 12 on the sapphire supporting base by a metal-organic chemical vapor deposition (MOCVD) process. The light-emitting unit 12 includes an epitaxial layer 120 and an electrode layer 130 sequentially stacked on a side of the supporting base 11. The epitaxial layer 120 includes a buffer layer 121, a first conductivity type semiconductor structure 122, a quantum well structure 123, a second conductivity type semiconductor structure 124, and an electric current spreading layer 125 that are sequentially stacked. The first conductivity type semiconductor structure 122 is n-GaN and is configured to provide electrons. The second conductivity type semiconductor structure 124 is p-GaN and is configured to provide holes. Under an influence of an external electric field, the electrons diffuse from the n-GaN to the quantum well structure 123, and the holes diffuse from the p-GaN to the quantum well structure 123. The electrons and the holes then are subject to transition and recombination processes in the quantum well structure 123, thereby radiating energy outwardly in the form of photons and emitting light. In other words, the quantum well structure 123 serves as a light-emitting layer of the light-emitting unit 12. The electric current spreading layer 125 is an Indium tin oxide (ITO) layer. The electrode layer 130 includes a P-type electrode 131 and an N-type electrode 132. The P-type electrode 131 and the N-type electrode 132 are spaced apart and insulated from each other. The light-emitting substrate 10 further includes a silicon oxide insulating layer 13. A mesa structure or a boss structure is formed by performing a plasma (e.g., inductively coupled plasma, ICP) etching process on the epitaxial layer 120, and the silicon oxide insulating layer 13 is deposited on a side of the epitaxial layer 120 away from the supporting base 11. In this way, the P-type electrode 131 and the N-type electrode 132 of the electrode layer 130 are separated from each other. The quantum well structure 123 may be a single quantum well region, or a multiple quantum well region. In the present embodiment, the quantum well structure 123 is a multiple quantum wells region.

In some other embodiments, the light-emitting unit 12 may include other structures and may be fabricated through other preparation methods.

The light-emitting unit 12 may include the supporting base 11. A plurality of light-emitting units 12 share a same supporting base 11. This light-emitting substrate 10 is an array substrate of the light-emitting units 12.

At block S200: preparing the first film layer on a side of the light-emitting substrate and defining the groove on a side surface of the first film layer away from the light-emitting substrate, wherein one groove is defined corresponding to one light-emitting unit.

Specifically, preparing the first film layer 20 on a side of the light-emitting substrate 10, and defining the groove 21 on a side surface of the first film layer 20. One groove 21 is defined corresponding to one light-emitting unit 12.

The groove 21 is connected to the side surface of the first film layer 20 away from the light-emitting substrate 10. In a direction perpendicular to the light-emitting substrate 10, the groove 21 is spaced apart from the corresponding light-emitting unit 12. A spacing between the grooves 21 is related to that between the light-emitting units 12. Shapes, sizes, depths of the grooves 21 and the spacings between the grooves are not restricted here and may be selected per actual requirements.

A cross section of the groove 21 in the direction perpendicular to the light-emitting substrate 10 may be a rectangle, a trapezoid, or other shapes. In the present embodiment, the cross section of the groove 21 in the direction perpendicular to the light-emitting substrate 10 is a rectangle.

In implementations of the present disclosure, the number of the grooves 21 is less than that of the light-emitting units 12. In other words, some of the light-emitting units 12 are not disposed corresponding to the grooves 21. That is, the grooves 21 are not defined on the side of some light-emitting units 12 away from the supporting base 11.

The first film layer 20 is made of transparent flexible material. Specifically, the first film layer 20 is polydimethylsiloxane (PDMS).

The first film layer 20 is made of transparent material, such that the light emitted by the light-emitting unit 12 may pass through the first film layer 20. That is, no groove 21 is defined on the side of the light-emitting unit 12 away from the supporting base 11. In some embodiments, the first film layer 20 is made of transparent material, such that the light emitted by the light-emitting unit 12 may be directed to a corresponding groove 21 via the first film layer 20.

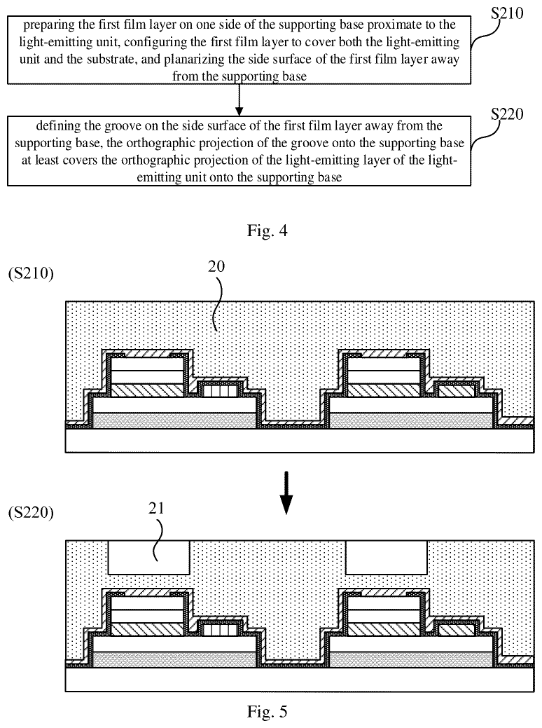

As illustrated in FIG. 2 to FIG. 5, FIG. 4 is a schematic flowchart of an implementation of the operation at block S200 of FIG. 1. FIG. 5 is a schematic structural diagram corresponding to the operations at block S210 and S220 of FIG. 4.

In some embodiments, the specific steps of the operation at block S200 (i.e., preparing the first film layer on a side of the light-emitting substrate and defining the groove on a side surface of the first film layer away from the light-emitting substrate) are as follows.

At block S210: preparing the first film layer on a side of the supporting base proximate to the light-emitting unit, configuring the first film layer to cover both the light-emitting unit and the supporting base, and planarizing the side surface of the first film layer away from the supporting base.

Specifically, preparing the first film layer 20 on a side of the supporting base 11 proximate to the light-emitting unit 12, configuring the first film layer 20 to cover both the light-emitting unit 12 and the supporting base 11, and planarizing the side surface of the first film layer 20 away from the supporting base 11.

Filling gaps between the light-emitting units 12 with a fluidic or fluid-like transparent flexible material, covering the light-emitting units 12 with the fluidic transparent flexible material, curing the fluidic transparent flexible material to obtain the first film layer 20, and planarizing the side surface of the first film layer 20 away from the supporting base 11. By filling the gaps between the light-emitting units 12 with the fluidic transparent flexible material, a contact area between the first film layer 20 and the light-emitting unit 12 may be increased, which is conducive to enhancing a bonding strength between the first film layer 20 and the light-emitting substrate 10. Planarizing the side surface of the first film layer 20 away from the supporting base 11 facilitates a close contact between the first film layer 20 and the second film layer 30 in a subsequent procedure, thereby reducing the gap between the surfaces of the first film layer 20 and the second film layer 30 in close proximity to each other, the specific effect of which may be described below.

At block S220: defining the groove on the side surface of the first film layer away from the supporting base, an orthographic projection of the groove onto the supporting base at least covers an orthographic projection of the light-emitting layer of the light-emitting unit onto the supporting base.

Specifically, defining the groove 21 on the side surface of the first film layer 20 away from the supporting base 11, the orthographic projection of the groove 21 onto the supporting base 11 at least covers the orthographic projection of the light-emitting layer of the light-emitting unit 12 onto the supporting base 11. The light-emitting layer is the above-mentioned quantum well structure 123.

In some embodiments, a mold may be adopted to press a side surface of the first film layer 20 away from the supporting base 11. After the mold is removed, the groove 21 is obtained.

In some other embodiments, the first film layer 20 may be etched to define the groove 21.

The defining approach of the groove 21 is not restricted here and may be selected per actual requirements.

The orthographic projection of the groove 21 onto the supporting base 11 may completely cover the orthographic projection of the light-emitting layer of the light-emitting unit 12 onto the supporting base 11. In some embodiments, the orthographic projection of the groove 21 onto the supporting base 11 may cover and extend beyond the orthographic projection of the light-emitting layer of the light-emitting unit 12 onto the supporting base 11. In this way, the light emitted by the light-emitting unit 12 may be directed towards the groove 21 as much as possible, thereby enhancing a utilization efficiency of the light emitted by the light-emitting unit 12.

In other words, the orthographic projection of the groove 21 onto the supporting base 11 is only required to cover the orthographic projection of the light-emitting layer of the light-emitting unit 12 onto the supporting base 11, and is not required to completely cover the orthographic projection of the whole of the corresponding light-emitting unit 12 onto the supporting base 11. This technical approach not only enhances the utilization efficiency of the light emitted by the light-emitting unit 12, but also reduces the cross-sectional area of the groove 21 in a direction parallel to the light-emitting substrate 10, thereby saving the cost of the material within the groove 21.

At block S300: preparing the second film layer and defining the draining cavity within the second film layer.

Specifically, preparing the second film layer 30, and defining the draining cavity 310 within the second film layer 30.

In implementations of the present disclosure, the second film layer 30 is prepared separately, rather than being prepared directly on the first film layer 20 or on the light-emitting substrate 10.

The operations at blocks S200 and S300 are not sequential relative to each other. The operation at block S200 may be performed before or after the operation at block S300. The operations at blocks S200 and S300 may also be performed simultaneously.

The second film layer 30 is made of transparent flexible material.

In the present embodiment, the operation at the block S200 is performed before the operation at block S300.

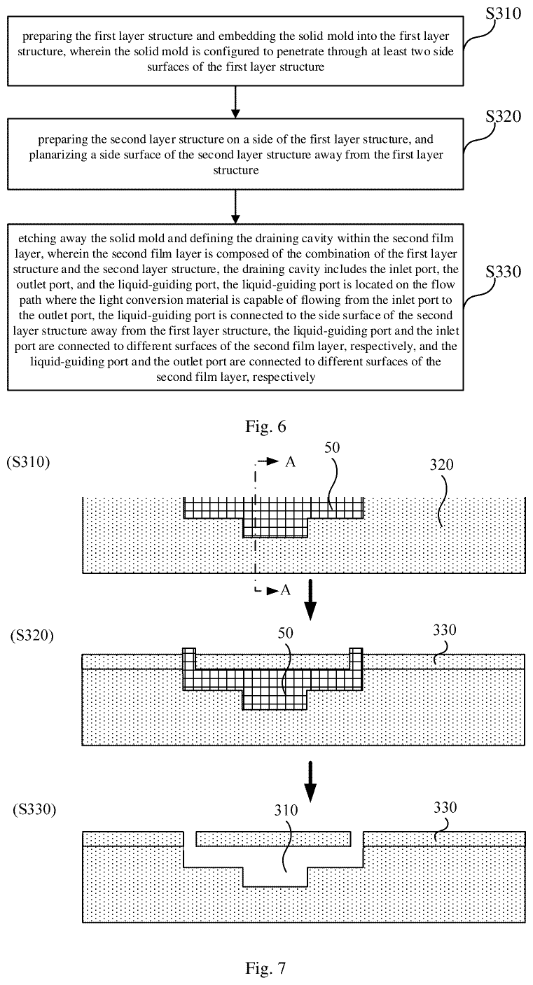

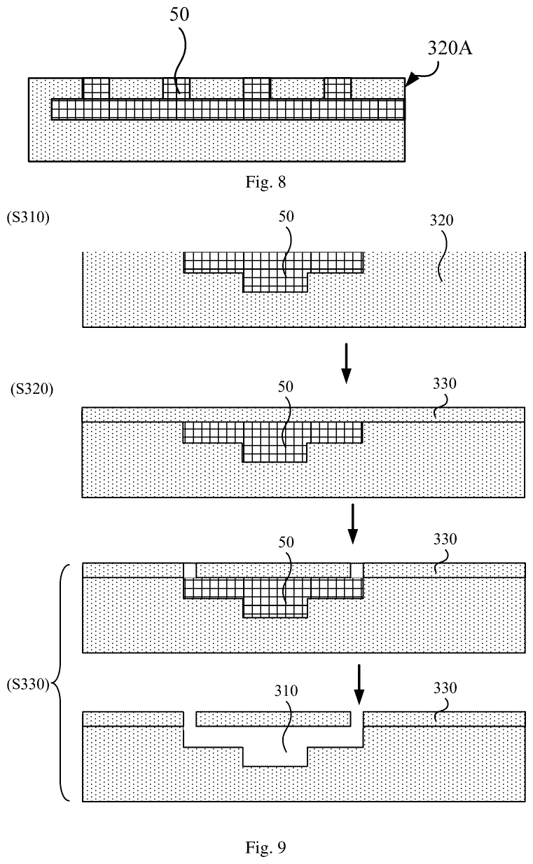

As illustrated in FIG. 2, FIG. 3, and FIG. 6 to FIG. 9, FIG. 6 is a schematic flowchart of an implementation of the operation at block S300 of FIG. 1, FIG. 7 is a schematic structural diagram corresponding to an implementation of the operations at blocks S310 to S330 of FIG. 6, FIG. 8 is a schematic sectional structural diagram along a direction A-A of FIG. 7, and FIG. 9 is a schematic structural diagram corresponding to another implementation of the operations at blocks S310 to S330 of FIG. 6.

The specific steps of the operation at block S300 (i.e., preparing the second film layer and defining the draining cavity within the second film layer) are as follows.

At block S310: preparing a first layer structure and embedding a solid mold into the first layer structure. The solid mold is configured to penetrate through at least two side surfaces of the first layer structure.

Specifically, preparing a first layer structure 320, and embedding a solid mold 50 into the first layer structure 320. The solid mold 50 is configured to penetrate through at least two side surfaces of the first layer structure 320, as illustrated in FIG. 8.

Preparing the first layer structure 320 on a temporary supporting base (not illustrated in the figures). Embedding the solid mold 50 into the first layer structure 320 before the first layer structure 320 is cured, and configuring the solid mold 50 to penetrate through a side surface of the first layer structure 320 away from the temporary supporting base, and to penetrate through at least one of the remaining side faces 320A of the first layer structure 320. The side face 320A of the first layer structure 320 is defined as a surface that is connected to the side surface of the first layer structure 320 away from the temporary supporting base.

In the present embodiment, the solid mold 50 is configured to penetrate through the side surface of the first layer structure 320 away from the temporary supporting base and to penetrate through the side face 320A of the first layer structure 320, as illustrated in FIG. 8.

An outer profile structure of the solid mold 50 is similar to a profile structure of the draining cavity 310.

At block S320: preparing a second layer structure on a side of the first layer structure, and planarizing a side surface of the second layer structure away from the first layer structure.

Specifically, preparing a second layer structure 330 on a side of the first layer structure 320, and planarizing a side surface of the second layer structure 330 away from the first layer structure 320.

Planarizing the side surface of the second layer structure 330 away from the first layer structure 320 facilitates a close contact between the first film layer 20 and the second film layer 30 in subsequent procedures, thereby reducing the gap between the surfaces of the first film layer 20 and the second film layer 30 in close proximity to each other. That is, the gap between the side surface of the second layer structure 330 away from the first layer structure 320 and the side surface of the first film layer 20 away from the light-emitting substrate 10 is reduced.

Preparing the second layer structure on a side of the first layer structure 320 away from the temporary supporting base. The solid mold 50 may either penetrate through the second layer structure 330 or may not penetrate through the second layer structure 330.

In some embodiments, as illustrated in FIG. 7, in response to the solid mold 50 being configured to penetrate through the second layer structure 330, an end portion of the solid mold 50 extends through the second layer structure 330 in the direction perpendicular to the first layer structure 320. The second layer structure 330 is configured to cover the side surface of the first layer structure 320 away from the temporary supporting base. By configuring the solid mold 50 to penetrate through the second layer structure 330, a portion of the solid mold 50 may be allowed to be exposed out of the second layer structure 330, thereby facilitating removing the solid mold 50 by direct etching in the subsequent procedures.

In some other embodiments, as illustrated in FIG. 9, in response to the solid mold 50 not penetrating through the second layer structure 330, the second layer structure 330 is configured to cover the solid mold 50 and covering the side surface of the first layer structure 320 away from the temporary supporting base. In response to the solid mold 50 doing not penetrate through the second layer structure 330, since the solid mold 50 is covered by the second layer structure 330, the second layer structure 330 needs to be etched first to expose a part of the solid mold 50, before further etching process can be performed to remove the solid mold 50.

When transferring the second film layer 30 to a side of the first film layer 20, the temporary supporting base and the second film layer 30 may be transferred together to the first film layer 20, or only the second film layer 30 may be transferred to the first film layer 20.

In the present embodiment, when transferring the second film layer 30 to a side of the first film layer 20, only the second film layer 30 may be transferred to the first film layer 20.

At block S330: etching away the solid mold and defining the draining cavity within the second film layer, where the second film layer is composed of the combination of the first layer structure and the second layer structure. The draining cavity includes an inlet port, an outlet port, and a fluid-guiding port. The fluid-guiding port is located on a flow path where the light conversion material is capable of flowing from the inlet port to the outlet port. The fluid-guiding port is connected to the side surface of the second layer structure away from the first layer structure. The fluid-guiding port and the inlet port are connected to different surfaces of the second film layer, respectively. The fluid-guiding port and the outlet port are connected to different surfaces of the second film layer, respectively.

Specifically, the solid mold 50 may be etched away by a dry etching approach or a wet etching approach to define a draining cavity 310 within the second film layer 30. The second film layer 30 is composed of the combination of the first layer structure 320 and the second layer structure 330.

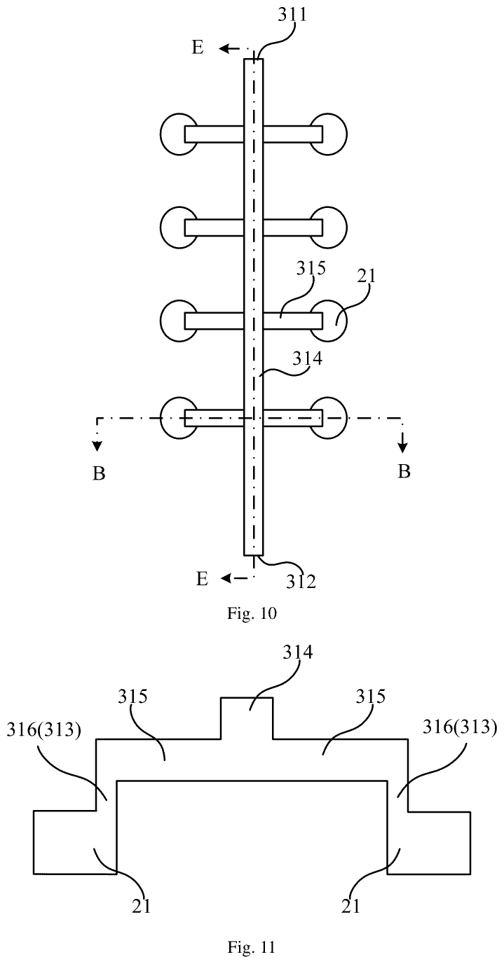

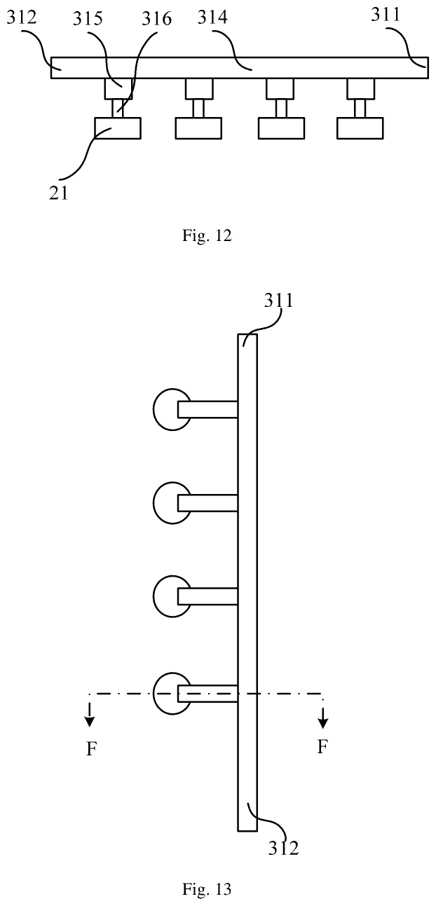

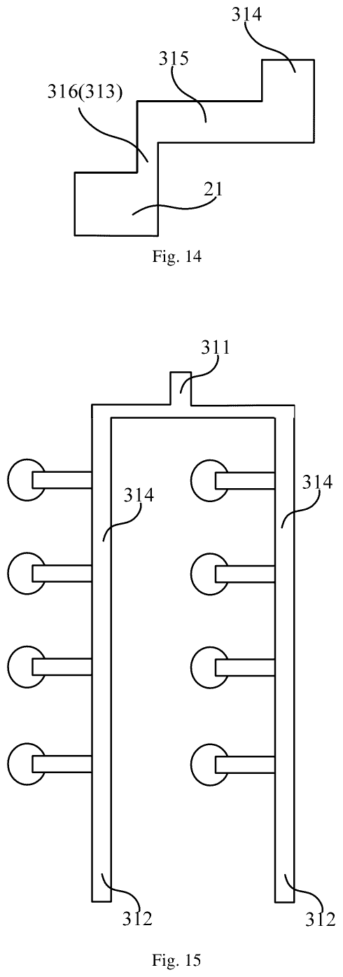

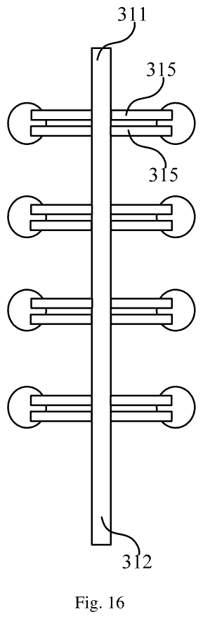

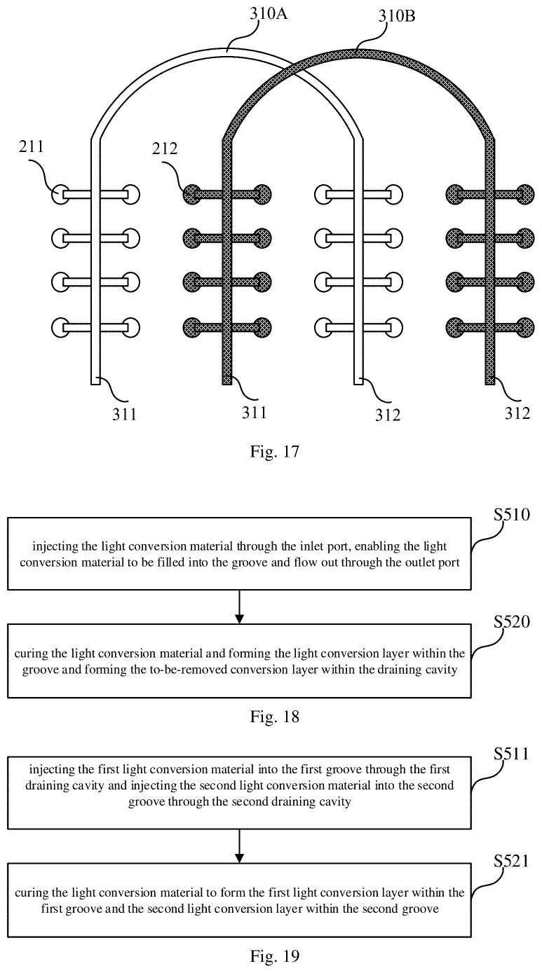

As illustrated in FIG. 2, FIG. 3, and FIG. 7 to FIG. 17, FIG. 10 is a top view schematic structural diagram of the draining cavity and the corresponding groove according a first embodiment of the present disclosure, FIG. 11 is a schematic sectional structural diagram along a direction B-B of FIG. 10, FIG. 12 is a schematic sectional structural diagram along a direction E-E of FIG. 10, FIG. 13 is a top view schematic structural diagram of the draining cavity and the corresponding groove according a second embodiment of the present disclosure, FIG. 14 is a schematic sectional structural diagram along a direction F-F of FIG. 13, FIG. 15 is a top view schematic structural diagram of the draining cavity and the corresponding groove according a third embodiment of the present disclosure, FIG. 16 is a top view schematic structural diagram of the draining cavity and the corresponding groove according a fourth embodiment of the present disclosure, and FIG. 17 is a top view schematic structural diagram of the draining cavity and the corresponding groove according a fifth embodiment of the present disclosure.

The draining cavity 310 includes an inlet port 311, an outlet port 312, and a fluid-guiding port 313. The fluid-guiding port 313 is connected to the side surface of the second layer structure 330 away from the first layer structure 320. The fluid-guiding port 313 and the inlet port 311 are connected to different surfaces of the second film layer 30, respectively. The fluid-guiding port 313 and the outlet port 312 are connected to different surfaces of the second film layer 30, respectively.

The inlet port 311 and the outlet port 312 may be connected to a same surface of the second film layer 30, or the inlet port 311 and the outlet port 312 may be connected to different surfaces of the second film layer 30, respectively. Specifically, both the inlet port 311 and the outlet port 312 are connected to the side surface 320A of the first layer structure 320, to prevent a situation where the second layer structure 330 blocks the inlet port 311 and the outlet port 312. In this situation, the light conversion material is uncapable of being injected into the draining cavity 310 through the inlet port 311, nor capable of flowing out of the second film layer 30 through the outlet port 312.

The fluid-guiding port 313 is located on the flow path where the light conversion material flows from the inlet port 311 to the outlet port 312. In this way, in a process of flowing from the inlet port 311 to the outlet port 312, the light conversion material may further flow out through the fluid-guiding port 313.

In response to the solid mold 50 being configured to penetrate through the second layer structure 330, the draining cavity 310 would be defined within the second film layer 30 by etching away the solid mold 50. In response to the solid mold 50 being not configured to penetrate through the second layer structure 330, to define the fluid-guiding port 313, it is necessary to etch a part of the second layer structure 330 first. The fluid-guiding port 313 is configured to extend through the second layer structure 330 in the direction perpendicular to the second layer structure 330, to expose a part of the solid mold 50. The solid mold 50 is then etched away through the fluid-guiding port 313, and the connected cavity within the second film layer 30 is defined as the draining cavity 310. In other words, after the solid mold 50 is removed, a space originally occupied by the solid mold 50 within the second film layer 30 is inter-connected with the fluid-guiding port 313, and collectively define the draining cavity 310.

The draining cavity 310 includes a first channel 314, a second channel 315 and a third channel 316. The inlet port 311 is a port of the first channel 314. The outlet port 312 is another port of the first channel 314. The second channel 315 is configured to communicate or connect the first channel 314 and the third channel 316. The third channel 316 and the second channel 315 are defined in one-to-one correspondence. The third channel 316 is the fluid-guiding port 313. An extension direction of the third channel 316 is configured to be perpendicular to the second layer structure 330 or inclined with respect to the second layer structure 330, such that the second channel 315 is spaced apart from the side surface of the second layer structure 330 away from the first layer structure 320. This configuration may reduce a contact area between the light conversion material cured in the draining cavity 310 and the side surface of the first film layer 20 away from the supporting base 11, thereby facilitating the separation of the first film layer 20 from the second film layer 30.

The first channel 314 may be construed as a main transport channel for the light conversion material, analogous to the trunk of a tree, while the second channel 315 may be construed as branching channels for the light conversion material, analogous to branches of a tree. There are a plurality of first channels 314. One first channel 314 is defined corresponding to a plurality of second channels 315. One second channel 315 is defined corresponding to one groove 21.

The first channel 314 may be a straight-line structure (as illustrated in FIG. 10, FIG. 13, and FIG. 16), a U-shaped structure (FIG. 17 and FIG. 18), an L-shaped structure (as illustrated in FIG. 15), or an S-shaped structure etc. No excess restrictions are imposed on the shape of the first channel 314 here. There may be a plurality of first channels 314. The plurality of first channels 314 may share a same inlet port 311, as illustrated in FIG. 15.

The structure of the first channel 314 is not restricted here and may be selected according to actual injection requirements.

In the present embodiment, the first channel 314 has a U-shape structure. Each of the two sides of one first channel 314 is provided with one second channel 315, to simultaneously deliver the light conversion material to two adjacent rows of grooves 21. Each of the two sides of each sidewall of the U-shaped structure in the first channel 314 is provided with a second channel 315, to accomplish a task of delivering the light conversion material to four rows of grooves 21 at a time.

The structure of the first channel 314 is related to an arrangement of the groove 21.

At block S400: aligning and closely attaching the second film layer with the first film layer and configuring the draining cavity to be in communication with the groove.

Specifically, aligning and closely attaching the second film layer 30 with the first film layer 20, and configuring the draining cavity 310 to be in communication with the groove 21.

In the second film layer 30, the side surface of the second layer structure 330 that is away from the first layer structure 320 is aligned with the side surface of the first film layer 20 that is away from the light-emitting substrate 10, such that the fluid-guiding port 313 of the draining cavity 310 directly communicates with the groove 21.

One groove 21 is configured corresponding to at least one fluid-guiding port 313. In other words, one groove 21 may be configured corresponding to one fluid-guiding port 313 or corresponding to a plurality of fluid-guiding ports 313.

In some embodiments, one groove 21 is configured corresponding to one fluid-guiding port 313. In comparation with an implementation where one groove 21 is configured corresponding to a plurality of fluid-guiding ports 313, in the design where one groove 21 is configured corresponding to one fluid-guiding port 313, a pore diameter of the fluid-guiding port 313 will be larger. In this way, the speed at which the light conversion material flows into the corresponding groove 21 through the fluid-guiding port 313 may be accelerated.

In some other embodiments, one groove 21 is configured corresponding to a plurality of fluid-guiding ports 313, In comparation with an implementation where one groove 21 is configured corresponding to one fluid-guiding port 313, in the technical approach where one groove 21 is configured corresponding to a plurality of fluid-guiding ports 313, the pore diameter of the fluid-guiding port 313 may be appropriately reduced, thereby decreasing the contact area between the light conversion material cured in the fluid-guiding port 313 and the second film layer 30 in subsequent processes, making it easier to separate the second film layer 30 from the first film layer 20.

Further, the diameter of the fluid-guiding port 313 is greater than 3 micrometers, to ensure that the light conversion material may smoothly flow into the groove 21 through the fluid-guiding port 313. Otherwise, the light conversion material may clog at the fluid-guiding port 313 and fail to flow into the groove 21 smoothly.

A size of the light-emitting unit 12 determines the size of the groove 21, and the diameter of the fluid-guiding port 313 is related to the size of the groove 21.

In some embodiments, the light-emitting unit 12 is the micro light-emitting diode. One groove 21 is configured corresponding to one or two fluid-guiding ports 313, as illustrated in FIG. 16. The diameter of the fluid-guiding port 313 is less than 7 micrometers. This technical approach ensures that, the fluid-guiding port 313 provides a good fluid-guiding effect, while the diameter of the fluid-guiding port 313 is kept as small as possible.

In the present embodiment, an example is illustrated in which one groove 21 is configured corresponding to one fluid-guiding port 313.

The specific steps of the operation at block S400 (i.e., aligning and closely attaching the second film layer with the first film layer, and configuring the draining cavity to be in communication with the groove) include: covering the second film layer 30 on the side of the first film layer 20 away from the supporting base 11 and pressing the second film layer 30 and the first film layer 20 together, and configuring the fluid-guiding port 313 to be in direct communication with the groove 21. The orthographic projection of the fluid-guiding port 313 onto the first film layer 20 is located within the corresponding groove 21.

The second film layer 30 is covered on the side of the first film layer 20 away from the supporting base 11, the side surface of the first film layer 20 away from the supporting base 11 is closely attached to the side surface of the second layer structure 330 in the second film layer 30 that is away from the first layer structure 320, and the first film layer 20 and the second film layer 30 are pressed together. In this way, the gap between the first film layer 20 and the second film layer 30 is further reduced, thereby preventing the light conversion material from flowing into this gap during subsequent procedures. If the light conversion material has flowed into the gap, the removal of the second film layer 30 may be hindered.

The fluid-guiding port 313 of the draining cavity 310 is in direct communication with the groove 21, The communication between the fluid-guiding port 313 and the groove 21 is not achieved through other ports of the draining cavity 310.

This design, where the orthographic projection of the fluid-guiding port 313 onto the first film layer 20 is located within the corresponding groove 21, may reduce the contact area between the fluid-guiding port 313 and the surface of the first film layer 20. In this way, in subsequent procedures, the contact area between the cured light conversion material in the fluid-guiding port 313 and the surface of the first film layer 20 is reduced, thereby decreasing the bonding strength between the cured light conversion material in the fluid-guiding port 313 and the first film layer 20, which in turn facilitates the separation of the second film layer 30 from the first film layer 20.

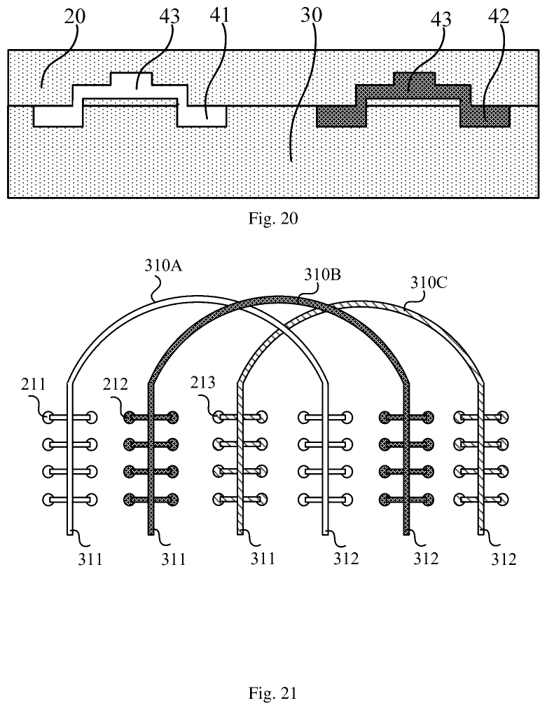

As illustrated in FIG. 2 to FIG. 21, FIG. 18 is a schematic flowchart of an implementation of the operation at block S500 of FIG. 1, FIG. 19 is a schematic flowchart of a specific implementation of the operation at block S500 of FIG. 1, FIG. 20 is a schematic structural diagram corresponding to the operation at block S521 of FIG. 19, and FIG. 21 is a top view schematic structural diagram of the draining cavity and the corresponding groove according a sixth embodiment of the present disclosure.

At block S500: injecting the light conversion material into the groove through the draining cavity and curing the light conversion material.

Specifically, injecting the light conversion material into the groove 21 through the draining cavity 310 and curing the light conversion material.

Injecting the light conversion material into the groove 21 through the fluid-guiding port 313 of the draining cavity 310 until the corresponding groove 21 is fully filled, then ceasing the injection of the light conversion material and curing the light conversion material.

The specific steps of the operation at block S500 (i.e., injecting the light conversion material into the groove through the draining cavity and curing the light conversion material) are as follows.

At block S510: injecting the light conversion material through the inlet port, such that the light conversion material is allowed to fill the groove and flow out through the outlet port.

The fluidic light conversion material is injected through the inlet port 311 of the draining cavity 310, the light conversion material flows into the groove 21 through the fluid-guiding port 313 of the draining cavity 310. Determining whether the groove 21 is fully filled with the light conversion material by checking if the light conversion material in the draining cavity 310 has flowed out through the outlet port 312.

Specifically, since the fluid-guiding port 313 is located on the flow path where the light conversion material flows from the inlet port 311 to the outlet port 312, i.e. the outlet port 312 is located at an end of the flow path of the light conversion material, the light conversion material, after flowing in through the inlet port 311, would first pass through the fluid-guiding port 313, then continues to the outlet port 312. Only after the groove 21 connected with the fluid-guiding port 313 is fully filled with the light conversion material, would the light conversion material pass the fluid-guiding port 313 and flow to the outlet port 312, and exit the second film layer 30. In other words, the light conversion material flowing out from the outlet port 312 may indicate that, the groove 21 is fully filled with the light conversion material, and injection of the light conversion material may be ceased. Additionally, both the inlet port 311 and the outlet port 312 are connected to the external atmosphere, which facilitates balancing the air pressures inside and outside the draining cavity 310 and facilitates the flow of the light conversion material inside the draining cavity 310.

At block S520: curing the light conversion material and forming the light conversion layer within the groove and forming a to-be-removed conversion layer within the draining cavity.

Specifically, curing the light conversion material and forming the light conversion layer 40 within the groove 21, and forming a to-be-removed conversion layer 43 within the draining cavity 310.

By curing the light conversion material, the cured light conversion material within the groove 21 may form the light conversion layer 40, and the cured light conversion material within the draining cavity 310 may form the to-be-removed conversion layer 43.

The light conversion layer 40 and the to-be-removed conversion layer 43 form an integrated structure.

The light conversion layer 40 may convert the light of one color into the light of another color.

In the present embodiment, the light conversion layer 40 includes quantum dot material. That is, the light conversion material is the quantum dot material.

In some other embodiments, the light conversion material may be phosphor or fluorescent powder.

In some embodiments, as illustrated in FIG. 17, the draining cavity 310 includes a first draining cavity 310A and a second draining cavity 310B that are not connected to each other. The light conversion material includes a first light conversion material and a second light conversion material. The groove 21 includes a first groove 211 and a second groove 212. The light conversion layer 40 includes a first light conversion layer 41 and a second light conversion layer 42. The specific steps of the operation at block S500 (i.e., injecting the light conversion material into the groove through the draining cavity and curing the light conversion material) are as follows.

At block S511: injecting the first light conversion material into the first groove through the first draining cavity and injecting the second light conversion material into the second groove through the second draining cavity.

Specifically, injecting the first light conversion material into the first groove 211 through the first draining cavity 310A, and injecting the second light conversion material into the second groove 212 through the second draining cavity 310B. No more will be elaborated here about the specific implementation, for more details, please refer to the above-mentioned descriptions.

The first light conversion material is red quantum dot material, which may convert the blue light emitted by the light-emitting unit 12 into the red light. The second light conversion material is green quantum dot material, which may convert the blue light emitted by the light-emitting unit 12 into the green light.

By adjusting an injection pressure of the light conversion material, the flow rate of the light conversion material may be controlled, thereby controlling the process time. Next, injecting the first light conversion material into the first groove 211 through the first draining cavity 310A, and simultaneously, injecting the second light conversion material into the second groove 212 through the second draining cavity 310B. In comparison with the related art, where the red quantum dot and the green quantum dot are prepared sequentially, this approach may significantly reduce the process time.

The flowing speed and the injecting approach of the light conversion material are not restricted here and may be selected per actual requirements.

At block S521: curing the light conversion material to form the first light conversion layer within the first groove and the second light conversion layer within the second groove.

Specifically, curing the light conversion material to form the first light conversion layer 41 within the first groove 211 and the second light conversion layer 42 within the second groove 212. No more will be elaborated here about the specific implementation, for more details, please refer to the above-mentioned descriptions.

At block S600: removing the second film layer.

Specifically, removing the second film layer 30.

Removing the second film layer 30 and the to-be-removed conversion layer 43, while retaining the light conversion layer 40 within the groove 21. In other words, separating the second film layer 30 from the first film layer 20, and separating the to-be-removed conversion layer 43 within the second film layer 30 from the light conversion layer 40 within the first film layer 20.

By reducing the gap between the surfaces of the first film layer 20 and the second film layer 30 that are facing each other, the to-be-removed conversion layer 43 may be prevented from being filled into this gap. If the to-be-removed conversion layer 43 has been filled into this gap, the contact area between the to-be-removed conversion layer 43 and the side surface of the first film layer 20 away from the supporting base 11 may be increased, making it more difficult to separate the to-be-removed conversion layer 43 from the light conversion layer 40 of the integrated structure, which in turn hinders the separation between the first film layer 20 and the second film layer 30.

By removing the second film layer 30 and removing the to-be-removed conversion layer in the second film layer 30, the cured light conversion material located at a side edge of the groove 21 may be removed, thereby avoiding interference with light emission by the to-be-removed conversion layer 43 in the second film layer 30, and thereby preventing the light crosstalk phenomenon.

Additionally, the presence of the light conversion layer 40 within the groove 21 does not require an extra light shield layer.

In some other embodiments, the draining cavity 310 may include more draining cavities 310 that are not connected to each other. The light conversion material may further include a third light conversion material. For example, as illustrated in FIG. 21, the draining cavity 310 includes the first draining cavity 310A, the second draining cavity 310B and a third draining cavity 310C that are not connected to each other. The groove 21 may further include a third groove 213.

The third light conversion material may be a mixture of the red quantum dot material and the green quantum dot material. In some embodiments, the third light conversion material may be another material capable of light conversion. The third light conversion material is not restricted herein and may be selected per actual requirements.

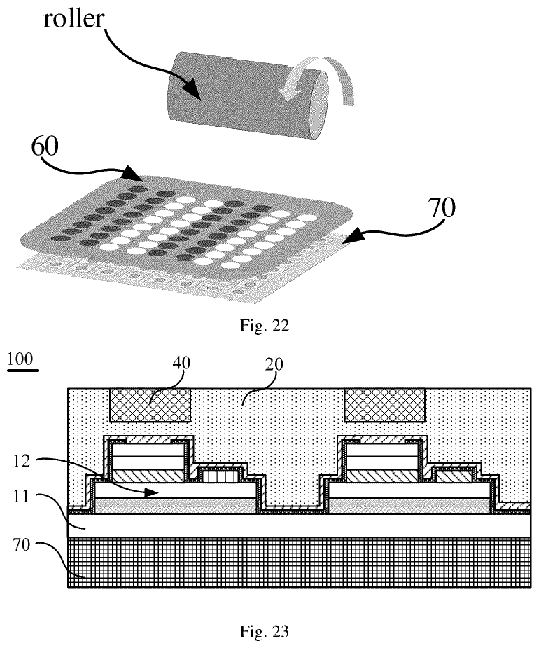

As illustrated in FIG. 1 to FIG. 22, FIG. 22 is a schematic diagram of a roller transfer printing process of the present disclosure.

After the operation at block S600: removing the first film layer, the method may further include the operation at block S700 of FIG. 1: combining the first film layer and the light-emitting substrate to form a to-be-transferred substrate, and transferring the to-be-transferred substrate to a driving substrate by a roller transfer printing process. The driving substrate is configured to drive the light-emitting unit to emit light.

Specifically, combining the first film layer 20 and the light-emitting substrate 10 to form a to-be-transferred substrate 60, and transferring the to-be-transferred substrate 60 to a driving substrate 70 by the roller transfer printing process. The driving substrate 70 is configured to drive the light-emitting unit 12 to emit light.

In the related art, the array of light-emitting units 12 is first transferred to the driving substrate 70 by a mass transfer technique. Then the red and green quantum dot conversion layers are prepared separately. The prepared red and green quantum dot conversion layers are then transferred to the array of light-emitting units 12. In comparison with this related art, in the implementation provided in the present disclosure, the light conversion layer 40 is directly prepared on the light-emitting substrate 10, resulting in higher alignment accuracy between the light-emitting unit 12 and the light conversion layer 40. The light conversion efficiency of the light conversion layer 40 may be further enhanced. Further, in embodiments of the present disclosure, the to-be-transferred substrate 60 is transfer printed to the driving substrate 70 as a transfer printing layer. In this way, the number of transfer and preparation steps may be reduced, thereby effectively enhancing the efficiency.

During the process of transferring the to-be-transferred substrate 60 to the driving substrate 70 by the roller transfer printing process, a hot-pressing process may be applied, so as to achieve better bonding strength between the first film layer 20 and the light-emitting substrate 10. Additionally, the first film layer 20 may also serve as a protective layer for the light conversion layer within the groove 21.

After transferring the to-be-transferred substrate 60 to the driving substrate 70, the first film layer 20 is disposed on the side of the light-emitting substrate 10 away from the driving substrate 70. The structure of the driving substrate 70 is not restricted here and may be selected according to actual injection requirements.

As illustrated in FIG. 2, FIG. 3 and FIG. 23, FIG. 23 is a schematic structural diagram of a display panel according to an embodiment of the present disclosure.

A display panel 100 is provided in the present disclosure. The display panel 100 is fabricated by any one of the above-mentioned preparation methods of the display panel.

The display panel 100 includes the driving substrate 70, the supporting base 11, the light-emitting unit 12 and the first film layer 20 sequentially stacked. The groove 21 is defined on the side of the first film layer 20 away from the supporting base 11. The light conversion layer 40 is disposed within the groove 21.

No more will be elaborated here about the structure of the display panel 100, for more details, please refer to the above-mentioned descriptions.

In the above-mentioned embodiments, a description of each embodiment has its own focus, and a part not detailed in a certain embodiment may be referred to relevant descriptions of other embodiments.

The above are only implementations of the present disclosure, and do not limit the patent scope of the present disclosure. Any equivalent changes to the structure or processes made by the description and drawings of this disclosure or directly or indirectly used in other related technical field are included in the protection scope of this disclosure.

What is claimed is:

1. A preparation method of a display panel, comprising:
providing a light-emitting substrate, wherein the light-emitting substrate comprises a supporting base and a light-emitting unit, the light-emitting unit is disposed on a side of the supporting base;
preparing a first film layer on a side of the light-emitting substrate, and defining a groove on a side surface of the first film layer away from the light-emitting substrate, wherein one groove is defined corresponding to one light-emitting unit;
preparing a second film layer, and defining a draining cavity within the second film layer;
aligning and closely attaching the second film layer with the first film layer, and configuring the draining cavity to be in communication with the groove;
injecting a light conversion material into the groove through the draining cavity and curing the light conversion material; and
removing the second film layer.

2. The preparation method of the display panel as claimed in claim 1, wherein
the operation of preparing the first film layer on the side of the light-emitting substrate, and defining
the groove on the side surface of the first film layer comprises:
preparing the first film layer on a side of the supporting base proximate to the light-emitting unit, configuring the first film layer to cover the light-emitting unit and the supporting base, and planarizing a side surface of the first film layer away from the supporting base; and
defining the groove on the side surface of the first film layer away from the supporting base, wherein an orthographic projection of the groove onto the supporting base at least covers an orthographic projection of a light-emitting layer of the light-emitting unit onto the supporting base.

3. The preparation method of the display panel as claimed in claim 1, wherein
the operation of preparing the second film layer, and defining the draining cavity within the second film layer comprises:
preparing a first layer structure, and embedding a solid mold into the first layer structure, wherein the solid mold is configured to penetrate through at least two side surfaces of the first layer structure;
preparing a second layer structure on a side of the first layer structure, and planarizing a side surface of the second layer structure away from the first layer structure; and
etching away the solid mold and defining the draining cavity within the second film layer, wherein the second film layer is composed of a combination of the first layer structure and the second layer structure, the draining cavity comprises an inlet port, an outlet port, and a fluid-guiding port, the fluid-guiding port is located on a flow path where the light conversion material is capable of flowing from the inlet port to the outlet port, the fluid-guiding port is connected to the side surface of the second layer structure away from the first layer structure, the fluid-guiding port and the inlet port are connected to different surfaces of the second film layer respectively, and the fluid-guiding port and the outlet port are connected to different surfaces of the second film layer respectively.

4. The preparation method of the display panel as claimed in claim 3, wherein
the operation of injecting the light conversion material into the groove through the draining cavity and curing the light conversion material comprises:
injecting the light conversion material through the inlet port, enabling the light conversion material to be filled into the groove and flow out through the outlet port; and
curing the light conversion material and forming a light conversion layer within the groove and forming a to-be-removed conversion layer within the draining cavity.

5. The preparation method of the display panel as claimed in claim 4, wherein
the draining cavity comprises a first draining cavity and a second draining cavity that are not connected to each other, the light conversion material comprises a first light conversion material and a second light conversion material, the groove comprises a first groove and a second groove; the light conversion layer comprises a first light conversion layer and a second light conversion layer;
the operation of injecting the light conversion material into the groove through the draining cavity and curing the light conversion material comprises:
injecting the first light conversion material into the first groove through the first draining cavity, and injecting the second light conversion material into the second groove through the second draining cavity; and
curing the light conversion material to form the first light conversion layer within the first groove and the second light conversion layer within the second groove.

6. The preparation method of the display panel as claimed in claim 3, wherein
one groove is configured corresponding to at least one fluid-guiding port; and
the diameter of the fluid-guiding port is greater than 3 micrometers.

7. The preparation method of the display panel as claimed in claim 6, wherein
the light-emitting unit is a micro light-emitting diode;
one groove is configured corresponding to one or two fluid-guiding port(s); and
the diameter of the fluid-guiding port is less than 7 micrometers.

8. The preparation method of the display panel as claimed in claim 6, wherein
the operation of aligning and closely attaching the second film layer with the first film layer, and configuring the draining cavity to be in communication with the groove comprises:
covering the second film layer on a side of the first film layer away from the supporting base and pressing the first film layer and the second film layer together, and configuring the fluid-guiding port to be in direct communication with the groove, wherein an orthographic projection of the fluid-guiding port onto the first film layer is located within a corresponding groove.

9. The preparation method of the display panel as claimed in claim 1, wherein
after the operation of removing the second film layer, the method further comprises:
combining the first film layer and the light-emitting substrate to form a to-be-transferred substrate and transferring the to-be-transferred substrate to a driving substrate by a roller transfer printing process,
wherein the driving substrate is configured to drive the light-emitting unit to emit light.

10. The preparation method of the display panel as claimed in claim 3, wherein
the draining cavity comprises a first channel, a second channel and a third channel;
the inlet port is a port of the first channel, and the outlet port is another port of the first channel;
the second channel is configured to connect the first channel and the third channel; and
the third channel is the fluid-guiding port.

11. A display panel, wherein
the display panel is prepared by a preparation method comprising:
providing a light-emitting substrate, wherein the light-emitting substrate comprises a supporting base and a light-emitting unit, the light-emitting unit is disposed on a side of the supporting base;
preparing a first film layer on a side of the light-emitting substrate, and defining a groove on a side surface of the first film layer away from the light-emitting substrate, wherein one groove is defined corresponding to one light-emitting unit;
preparing a second film layer, and defining a draining cavity within the second film layer;
aligning and closely attaching the second film layer with the first film layer, and configuring the draining cavity to be in communication with the groove;
injecting a light conversion material into the groove through the draining cavity and curing the light conversion material; and
removing the second film layer.

12. The display panel as claimed in claim 11, wherein
the operation of preparing the first film layer on the side of the light-emitting substrate, and defining
the groove on the side surface of the first film layer comprises:
preparing the first film layer on a side of the supporting base proximate to the light-emitting unit, configuring the first film layer to cover the light-emitting unit and the supporting base, and planarizing a side surface of the first film layer away from the supporting base; and
defining the groove on the side surface of the first film layer away from the supporting base, wherein an orthographic projection of the groove onto the supporting base at least covers an orthographic projection of a light-emitting layer of the light-emitting unit onto the supporting base.

13. The display panel as claimed in claim 11, wherein
the operation of preparing the second film layer, and defining the draining cavity within the second film layer comprises:
preparing a first layer structure, and embedding a solid mold into the first layer structure, wherein the solid mold is configured to penetrate through at least two side surfaces of the first layer structure;
preparing a second layer structure on a side of the first layer structure, and planarizing a side surface of the second layer structure away from the first layer structure; and
etching away the solid mold and defining the draining cavity within the second film layer, wherein the second film layer is composed of a combination of the first layer structure and the second layer structure, the draining cavity comprises an inlet port, an outlet port, and a fluid-guiding port, the fluid-guiding port is located on a flow path where the light conversion material is capable of flowing from the inlet port to the outlet port, the fluid-guiding port is connected to the side surface of the second layer structure away from the first layer structure, the fluid-guiding port and the inlet port are connected to different surfaces of the second film layer respectively, and the fluid-guiding port and the outlet port are connected to different surfaces of the second film layer respectively.

14. The display panel as claimed in claim 13, wherein
the operation of injecting the light conversion material into the groove through the draining cavity and curing the light conversion material comprises:
injecting the light conversion material through the inlet port, enabling the light conversion material to be filled into the groove and flow out through the outlet port; and
curing the light conversion material and forming a light conversion layer within the groove and forming a to-be-removed conversion layer within the draining cavity.

15. The display panel as claimed in claim 14, wherein
the draining cavity comprises a first draining cavity and a second draining cavity that are not connected to each other, the light conversion material comprises a first light conversion material and a second light conversion material, the groove comprises a first groove and a second groove; the light conversion layer comprises a first light conversion layer and a second light conversion layer;
the operation of injecting the light conversion material into the groove through the draining cavity and curing the light conversion material comprises:
injecting the first light conversion material into the first groove through the first draining cavity, and injecting the second light conversion material into the second groove through the second draining cavity; and
curing the light conversion material to form the first light conversion layer within the first groove and the second light conversion layer within the second groove.

16. The display panel as claimed in claim 13, wherein
one groove is configured corresponding to at least one fluid-guiding port; and
the diameter of the fluid-guiding port is greater than 3 micrometers.

17. The display panel as claimed in claim 16, wherein
the light-emitting unit is a micro light-emitting diode;
one groove is configured corresponding to one or two fluid-guiding port(s); and
the diameter of the fluid-guiding port is less than 7 micrometers.

18. The display panel as claimed in claim 16, wherein
the operation of aligning and closely attaching the second film layer with the first film layer, and configuring the draining cavity to be in communication with the groove comprises:
covering the second film layer on a side of the first film layer away from the supporting base and pressing the first film layer and the second film layer together, and configuring the fluid-guiding port to be in direct communication with the groove, wherein an orthographic projection of the fluid-guiding port onto the first film layer is located within a corresponding groove.

19. The display panel as claimed in claim 11, wherein
after the operation of removing the second film layer, the method further comprises:
combining the first film layer and the light-emitting substrate to form a to-be-transferred substrate and transferring the to-be-transferred substrate to a driving substrate by a roller transfer printing process,
wherein the driving substrate is configured to drive the light-emitting unit to emit light.

20. The display panel as claimed in claim 13, wherein
the draining cavity comprises a first channel, a second channel and a third channel;
the inlet port is a port of the first channel, and the outlet port is another port of the first channel;
the second channel is configured to connect the first channel and the third channel; and
the third channel is the fluid-guiding port.
